(19) United States
(12) Patent Application Publication
(10) Pub. No.: US 2004/0206955 A1
(43) Pub. Date: Oct. 21, 2004

(54) THIN-FILM TRANSISTOR

(76) Inventor: Kun-Hong Chen, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/708,640

(22) Filed: Mar. 17, 2004

(30) Foreign Application Priority Data
Apr. 17, 2003 (TW) 092108996

(51) Int. Cl. H01L 29/04

(52) U.S. Cl. 257/59

(57) ABSTRACT

A thin-film transistor includes a substrate, a semiconductor layer and a gate positioned on the substrate. The semiconductor layer has a channel region, two lightly doped drains and two source/drain regions. The two lightly doped drains are symmetrically arranged with respect to the gate. Either of the gate edges overlaps with portions of the adjacent lightly doped drain. Neither of the junctions between the lightly doped drains and the source/drain regions overlaps with the gate. Neither of the source/drain regions overlaps with the gate.

### BACKGROUND OF INVENTION

1. Field of the Invention

The present invention relates to a thin-film transistor.

2. Description of the Prior Art

From the fact that a thin-film transistor having an active layer formed of a crystalline silicon film on a substrate having an insulating surface has a high electric field effect mobility, it is possible to form a variety of functional circuits. For example, in the active matrix liquid crystal device (AMLCD) employing the crystalline silicon thin-film transistor, a thin-film transistor used as a pixel switch is formed in every pixel of an image display region, and a thin-film transistor used in a drive circuit is formed in the periphery of the image display region.

Since the functions and the operating conditions of the thin-film transistors in the pixel and the drive circuit are not the same, the characteristics that are demanded for a thin-film transistor is somewhat different. For example, the pixel thin-film transistor is demanded to function as a switch device for applying a voltage to a liquid crystal, so as to control the rotation angle of the liquid crystal. In this case, the characteristic that is demanded for the pixel thin-film transistor was to sufficiently lower an off-current value (a drain current that flows during an off-operation of the thin-film transistor), so as to maintain sufficient electric charges in a pixel storage capacitor, reduce a refresh frequency of the storage capacitor, and improve the power consumption conditions of the liquid crystal display.

FIG. 1 illustrates a cross-sectional diagram of a thin-film transistor according to the prior art, and an energy-band diagram of a gate edge region (the region circled with a dotted line) of the thin-film transistor. A thin-film transistor 10 includes a substrate 12, a semiconductor layer 13 positioned on the substrate 12, a gate insulating layer 24 positioned on the semiconductor layer 13, and a gate 26 positioned on the gate insulating layer 24. The semiconductor layer 13 includes two symmetric lightly doped drains 16, 18, and two symmetric source/drain regions 20, 22 positioned on either sides of the gate 26. The semiconductor layer 13 further includes a channel region 14 defined between the lightly doped drain 16 and the lightly doped drain 18.

In a conventional method of forming the thin-film transistor 10, a self-alignment process is usually used to form the source/drain regions 20 and 22. In this case, the gate 26 is formed prior to the formation of the source/drain regions 20 and 22. After the gate 26 is formed, an ion implantation process is performed using the gate 26 as a mask, thus forming the self-aligned source/drain regions 20, 22 on either sides of the gate 26. The self-alignment process has an advantage of saving a mask and a photolithographic process to pattern the source/drain regions, but it is not easy to control the device electrical characteristics while using this method. For example, the self-alignment process forms the gate edge region (the region circled with the dotted line) to overlap with the junction between the source/drain region 20 and the lightly doped drain 16. In some cases, the gate edge region may overlap with portions of the surface of the source/drain region 20. As shown in the energy-band diagram of FIG. 1, the defect energy level (Et) of the portion of the source/drain region 20 adjacent to the edge of the gate 26 is not very high. As a result, it is easy for the valence electrons within the semiconductor layer 13 to get energies to jump from the valence band (Ev) to the conductive band (Ec) to become free electrons, thus inducing leakage currents at the off-operation of the thin-film transistor to affect the quality of the display.

### SUMMARY OF INVENTION

It is therefore an object of the claimed invention to provide a thin-film transistor to reduce leakage currents thereof.

According to the claimed invention, the thin-film transistor includes a substrate, a semiconductor layer and a gate positioned on the substrate. The semiconductor layer includes a channel region, two lightly doped drains, and two source/drain regions. The two lightly doped drains are symmetrically arranged with respect to the gate. Either of the two gate edges is overlapped with the adjacent lightly doped drain. Neither of the junctions between the lightly doped drains and the source/drain regions is overlapped with the gate, and neither of the source/drain regions is overlapped with the gate.

It is an advantage of the claimed invention that the gate edges of the thin-film transistor are not overlapped with the portions of the semiconductor layer having lower defect energy levels, such as the source/drain regions and the junctions between the lightly doped drains and the source/drain regions. As a result, the valence electrons within the semiconductor layer cannot jump from the valence band to the conductive band easily at the off-operation of the thin-film transistor, thus reducing leakage currents thereof.

These and other objects of the claimed invention will be apparent to those of ordinary skill in the art after reading the following detailed description of the preferred embodiment that is illustrated in the various figures and drawings.

### BRIEF DESCRIPTION OF DRAWINGS

FIG. 1 illustrates a cross-sectional diagram of a thin-film transistor and an energy-band diagram of the thin-film transistor according to the prior art;

FIGS. 2-4 illustrate a method of fabricating a thin-film transistor according to the present invention;

FIG. 5 illustrates a correlation between a gate width and a leakage current value of a thin-film transistor; and

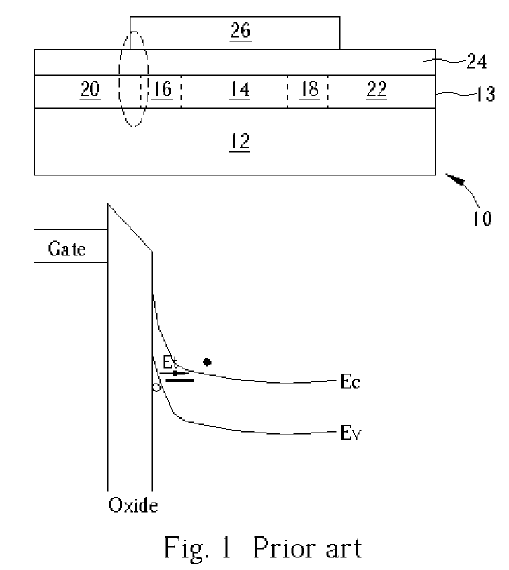

Table 1 shows correlations of a gate width with respect to various electrical parameters of a thin-film transistor.

### DETAILED DESCRIPTION

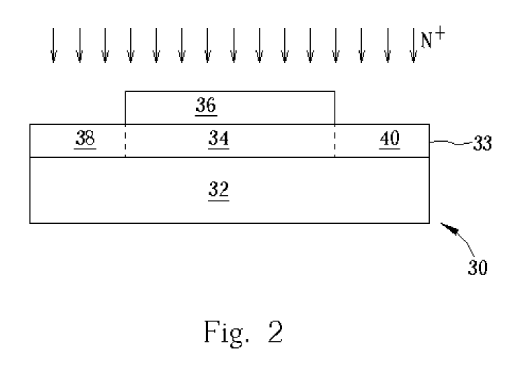

FIGS. 2-4 illustrate a method of fabricating a thin-film transistor 30 according to the present invention. The thin-film transistor 30 is used as a pixel switch or may also be used in other functional circuits in a liquid crystal display or in other electronic products. Normally, the thin-film transistor 30 is an n-type thin-film transistor. However, the thin-film transistor 30 may also be a p-type thin-film transistor according to the present invention.

As shown in FIG. 2, a substrate 32, such as a glass substrate, is provided. A semiconductor layer 33, such as a polysilicon layer, is formed on the substrate 32. Following that, a photolithographic process is performed to form a mask layer 36 on a channel region 34 of the semiconductor layer 33, so as to define patterns and positions of a source and a drain of the thin-film transistor 30. An ion implantation process is then performed to form two N+ doped regions 38 and 40 in the semiconductor layer 33 at either sides of the mask layer 36. The N+ doped regions 38 and 40 are used as source/drain regions of the thin-film transistor 30. In order to prevent damages to the crystal structure of the surface of the semiconductor layer 33, a sacrificial layer (not shown) is formed to cover the surface of the semiconductor layer 33 prior to the ion implantation process. The sacrificial layer can be an oxide layer formed by using a deposition method or a thermal oxidation method.

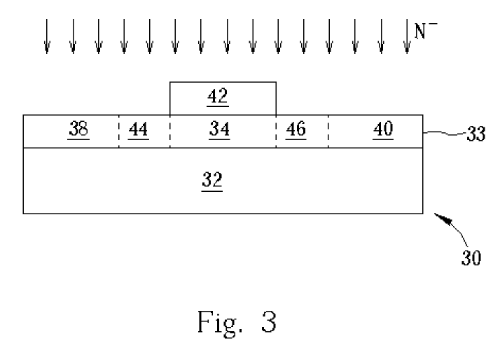

As shown in FIG. 3, after removing the mask layer 36, another mask layer 42 is formed on the semiconductor layer 33 to define patterns and positions of lightly doped drains of the thin-film transistor 30. An ion implantation process is then used to form two N− doped regions 44 and 46 in the semiconductor layer 33 at either sides of the mask layer 42. Subsequently, after removing the mask layer 42, a heat treatment is used to activate the ions implanted into the doped regions 38, 40, 44 and 46, thus completing the fabrication of the source/drain regions 38, 40, and the lightly doped drains 44, 46 together.

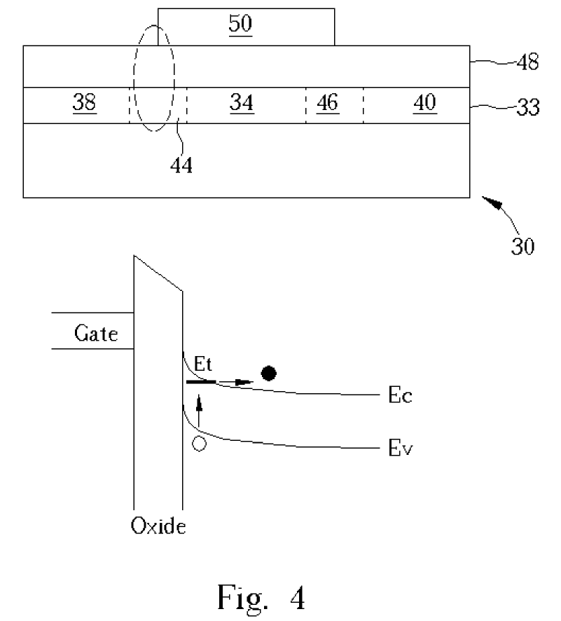

As shown in FIG. 4, a gate insulating layer 48 is formed on the semiconductor layer 33, and a conductive layer, such as a metal layer or a doped polysilicon layer, is formed on the gate insulating layer 48. Following that, a photolithographic process and an etching process are used to remove portions of the conductive layer, so as to form a gate 50 and complete the thin-film transistor 30. In a better embodiment of the present invention, the lightly doped drains 44 and 46 are symmetrically arranged with respect to the gate 50 and have the same lengths. The left edge and the right edge of the gate 50 overlap the lightly doped drain 44 and the lightly doped drain 46, respectively. In particular, the left edge and the right edge of the gate 50 are prevented from overlapping the source/drain regions 38, 40, the junction between the lightly doped drain 44 and the source/drain region 38, and the junction between the lightly doped drain 46 and the source/drain region 40.

Please refer to an energy-band diagram shown in the lower portion of FIG. 4. From the left side to the right side in the energy-band diagram, energy levels of the portions of the gate 50, the gate insulating layer 48 and the semiconductor layer (active layer) 33 within a gate edge region (the region circled with a dotted line) of the thin-film transistor 30 are illustrated. As shown in the energy-band diagram, the defect energy level (Et) of the portion of the lightly doped drain 44 adjacent to the edge of the gate 50 is very close to the energy level Ec of the conductive band. As a result, the valence electrons within the semiconductor layer 33 cannot easily get energies to jump from the valence band (Ev) to the conductive band (Ec) to become free electrons in unexpected situations. Therefore, the leakage current problems can be effectively prevented.

In general, a voltage (electric field) remains between the drain and the substrate when the transistor is turned off, thus generating leakage currents. Since the leakage current problems are more sensitive around the drain, the leakage currents can be reduced by overlapping a edge of the gate 50 with the lightly doped drain adjacent to the drain, and preventing the edge of the gate 50 from overlapping with either of the junction between the drain and the lightly doped drain or the drain. In addition, whether it is necessary to overlap the other edge of the gate 50 with the lightly doped drain adjacent to the source and keep it away from the junction between the lightly doped drain and the source or not can be an optional design choice according to the device characteristic demands of the transistor.

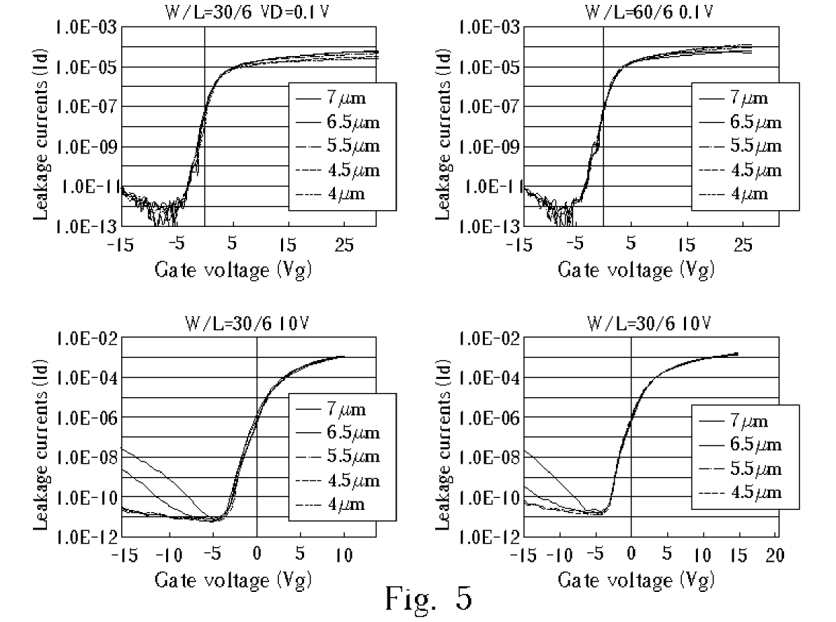

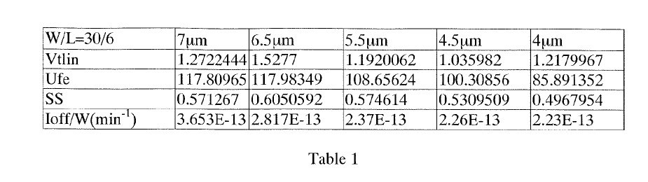

FIG. 5 illustrates a correlation between a gate width and a leakage current value of a thin-film transistor. Assume that a channel region of the thin-film transistor has a length of 4.5 μm and two lightly doped drains of the thin-film transistor have an equal length of 1 μm. As a result, both edges of a gate of the thin-film transistor would be approximately aligned with the junctions between the lightly doped drains and the adjacent source/drain regions when the gate has a width of 6.5 μm. In addition, when the gate width is greater than 6.5 μm, the both edges of the gate may overlap with portions of the source/drain regions. When the gate width is less than 6.5 μm, the both edges of the gate may overlap with the lightly doped drains instead of the source/drain regions. As shown in FIG. 5, when the gate width increases from 4 μm to 7 μm, the power of the leakage current increases approximately three orders of magnitude (for example the leakage current may increase from 10⁻¹¹ to 10⁻⁸). In other words, the leakage currents increase when the gate edge moves from atop the lightly doped drains to approach to the source/drain regions.

Table 1 shows correlations of a gate width with respect to various electrical parameters of a thin-film transistor. The lengths of the lightly doped drains and the channel region are assumed to have the same values as defined in the above paragraph. When the gate width is less than 6.5 μm (i.e. the gate edges are atop the lightly doped drains), electron mobility Ufe decreases when decreasing the gate width. In order words, when the gate edges moves from adjacent to the junction between the lightly doped drains and the source/drain regions toward the channel region, the electron mobility decreases to reduce the leakage currents, thus improving power consumption conditions of the thin-film transistor.

In a better embodiment of the present invention, a critical device structure is provided to more effectively reduce leakage currents. Assume that a gate width is defined as A, a channel length is defined as B, and a length of two lightly doped drains are defined as C. A correlation among these parameters is suggested to B+0.2C≦0.5A≦B+0.8C, wherein C is between 0.3 and 3.5 μm.

The present invention is characterized by adjusting the relative positions of the lightly doped drains, the drain and the gate edge. The gate edge is prevented from overlapping with the junction between the lightly doped drain and the drain, and the gate edge is prevented from overlapping with the drain, so as to reduce leakage currents. The present invention is not limited in the top-gate thin-film transistor, which has the gate positioned above the semiconductor layer, as mentioned in the above paragraphs. A bottom-gate thin-film transistor, which has a gate positioned below a semiconductor layer, may also be applied in the present invention to adjust the positions of the lightly doped drains, the drain and the gate edge. In this case, the gate insulating layer and the gate are formed on the substrate firstly. Following that, an insulating layer and the semiconductor layer including the lightly doped drains and the source/drain regions are formed above the gate. The relative positions of the lightly doped drains, the drain and the gate edge should be adjusted, so as to achieve the advantages of reducing leakage currents of the present invention.

In contrast to the prior art, the present invention adjusts the gate width or the relative positions of the gate edges, the lightly doped drains and the source/drain regions, so that the gate edges of the thin-film transistor are not overlapped with the positions having lower defect energy levels, such as the source/drain regions and the junctions between the lightly doped drains and the source/drain regions. As a result, the valence electrons within the semiconductor layer cannot jump from the valence band to the conductive band easily at the off-operation of the thin-film transistor, thus reducing leakage currents thereof.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A thin-film transistor comprising:
a substrate;
a semiconductor layer positioned on the substrate, the semiconductor layer comprising a channel region, two lightly doped drains, and two source/drain regions; and
a gate positioned on the substrate, the two lightly doped drains being symmetrically arranged with respect to the gate, either of the two gate edges being overlapped with the adjacent lightly doped drain, neither of the junctions between the lightly doped drains and the source/drain regions being overlapped with the gate, and neither of the source/drain regions being overlapped with the gate.

2. The thin-film transistor of claim 1 wherein the gate is positioned above the semiconductor layer.

3. The thin-film transistor of claim 1 wherein the gate is positioned below the semiconductor layer.

4. The thin-film transistor of claim 1 further comprising an insulating layer positioned between the gate and the semiconductor layer.

5. The thin-film transistor of claim 1 wherein the substrate comprises a glass substrate.

6. The thin-film transistor of claim 1 wherein the gate comprises a length A, the channel region comprises a length B, the lightly doped drains comprise a length C, and a correlation among these lengths is as following: B+0.2C≦0.5A≦B+0.8C.

7. The thin-film transistor of claim 1 wherein the lightly doped drains have an equal length.

8. The thin-film transistor of claim 1 wherein a length of the lightly doped drains is approximately between 0.3-3.5 μm.

9. A thin-film transistor comprising:
a substrate;
a semiconductor layer positioned on the substrate, the semiconductor layer comprising a channel region, two lightly doped drains, a source and a drain;
an insulating layer positioned on the semiconductor layer; and
a gate positioned on the insulating layer, the gate comprising a gate edge overlapped with the lightly doped drain adjacent to the drain, the gate being not overlapped with the junction between the lightly doped drain and the drain, and the gate being not overlapped with the drain.

10. The thin-film transistor of claim 9 wherein the gate comprises another gate edge overlapped with the lightly doped drain adjacent to the source, but the gate is not overlapped with the junction between the lightly doped drain and the source, and the gate is not overlapped with the source.

11. The thin-film transistor of claim 9 wherein the substrate comprises a glass substrate.

12. The thin-film transistor of claim 9 wherein the gate comprises a length A, the channel region comprises a length B, the lightly doped drain adjacent to the drain comprise a length C, and a correlation among these lengths is as following: B+0.2C≦0.5A≦B+0.8C.

13. The thin-film transistor of claim 9 wherein the lightly doped drains have an equal length.

14. The thin-film transistor of claim 9 wherein a length of the lightly doped drains is approximately between 0.3-3.5 μm.

15. The thin-film transistor of claim 9 wherein the lightly doped drains are symmetrically arranged with respect to the gate.
